(19) United States
(12) Patent Application Publication
(10) Pub. No.: US 2026/0047282 A1
(43) Pub. Date: Feb. 12, 2026

(54) DISPLAY PANEL AND DISPLAY DEVICE

(71) Applicant: HKC CORPORATION LIMITED, Shenzhen (CN)

(72) Inventors: Qiuyue Guo, Shenzhen (CN); Lei Hu, Shenzhen (CN); Jie Yang, Shenzhen (CN); Jinjing Fang, Shenzhen (CN); Yiran Wang, Shenzhen (CN); Li Lv, Shenzhen (CN); Haijiang Yuan, Shenzhen (CN)

(21) Appl. No.: 19/294,357

(22) Filed: Aug. 8, 2025

(30) Foreign Application Priority Data
Aug. 9, 2024 (CN) 202411098915.0

(51) Int. Cl. H10K 59/122; H10K 59/80

(52) U.S. Cl. CPC H10K 59/122; H10K 59/878

(57) ABSTRACT

The embodiment of the present application provides a display panel and a display device. The display panel includes a substrate, a drive circuit layer, a first anode layer, a pixel definition layer, a light-emitting layer, a second anode layer, a cathode layer, and a plurality of first reflective structures located in the pixel definition layer, and the first reflective structures correspond to the anti-peeping sub-pixels in a one-to-one correspondence, and the projection of the first reflective structure in the thickness direction of the display panel is located in the anti-peeping sub-pixel corresponding to the first reflective structure, and the first reflective structure is configured to reflect at least part of the light that are not perpendicular to the thickness direction of the display panel into the anti-peeping area.

### CROSS REFERENCE TO RELATED APPLICATION

Pursuant to 35 U.S. C. § 119 and the Paris Convention Treaty, the present application claims the benefit of Chinese Patent Application No. 202411098915.0 filed on Aug. 9, 2024, the contents of which are incorporated herein by reference.

### TECHNICAL FIELD

The present application relates to the technical field of display technology, and more particularly to a display panel and a display device.

### BACKGROUND

Display panel technology has made significant progress and development in recent years, especially in improving image quality, increasing energy efficiency, reducing costs and developing new functions. With the increasing application of display devices such as mobile phones and computers, people also pay special attention to the privacy of the use of display devices. In some cases, users wise that the information displayed in the display device will not be known by other users around them. Therefore, more and more display devices have anti-peeping functions.

Existing anti-peeping display panels are protected by anti-peeping films. When the anti-peeping function is not needed, the anti-peeping film can only be torn off, and the anti-peeping function is inconvenient to turn on and off. In order to solve the problem of inconvenience in turning on and off the anti-peeping function, some display panels are provided with anti-peeping units. After the anti-peeping unit is turned on, the display panel can display normally when looking straight ahead, and when looking at the side, the light emitted by the anti-peeping unit interferes with the light of the display unit, realizing anti-peeping when looking at the side. There is a reflection phenomenon in the OLED (Organic Light Emitting Diode) display device, which leads to low light utilization rate of the anti-peeping unit and weak light interference ability on the display unit, and results in unsatisfactory anti-peeping effect of the display panel.

### SUMMARY

In view of this, the embodiments of the present application provide a display panel and a display device to solve the technical problems of low light utilization rate and poor anti-peeping effect of the anti-peeping unit in the existing display panel.

In the first aspect, an embodiment of the present application provides a display panel, which includes:
a substrate;
a drive circuit layer, located on a side of the substrate;
a first anode layer, located on a side of the drive circuit layer away from the substrate, and the first anode layer includes a plurality of anodes;
a pixel definition layer, arrayed and arranged at intervals on a side of the first anode layer away from the substrate, and the pixel definition layer forms an anti-peeping area in a thickness direction of the display panel;
a light-emitting layer including a plurality of sub-pixels, and the plurality of sub-pixels are connected to the plurality of anodes in a one-to-one correspondence, the plurality of sub-pixels includes display sub-pixels and anti-peeping sub-pixels, the display sub-pixels are located on a side of the first anode layer away from the substrate and located between two adjacent pixel definition layers, the anti-peeping sub-pixels are located on a side of the pixel definition layer away from the substrate, and the display sub-pixels form a display area in the thickness direction of the display panel;
a second anode layer, located between the pixel definition layer and the anti-peeping sub-pixels, and the second anode layer includes a plurality of second anodes, and the plurality of second anodes are connected to the plurality of anti-peeping sub-pixels in a one-to-one correspondence;
a cathode layer, located on a side of the light-emitting layer away from the substrate;
a plurality of shading units, located on a side of the cathode layer away from the substrate, and the plurality of shading units are connected to the plurality of anti-peeping sub-pixels in a one-to-one correspondence, and a projection of each anti-peeping sub-pixel in the thickness direction of the display panel is located in the shading unit corresponding to the anti-peeping sub-pixel; and
a plurality of first reflective structures, located in the pixel definition layer, the plurality of first reflective structures are connected to the plurality of anti-peeping sub-pixels in a one-to-one correspondence, and a projection of each first reflective structure in the thickness direction of the display panel is located in the anti-peeping sub-pixel corresponding to the first reflective structure, and the first reflective structure is configured to reflect at least part of lights that are not perpendicular to the thickness direction of the display panel into the anti-peeping area.

In some embodiments, each of the plurality of first reflective structures includes:
a first reflector, configured to reflect external light and/or light emitted by the sub-pixel adjacent to the reflector;
a first color resist layer, covered on the first reflector, and the first color resist layer is configured to filter a color of light; and
a first electrochromic layer, covered on the first color resist layer, and the first electrochromic layer is connected to the first anode layer, the first electrochromic layer has a first state and a second state, the first electrochromic layer is black in color when the first electrochromic layer is in the first state, and the first electrochromic layer is transparent when the first electrochromic layer is in the second state for light to enter.

In some embodiments, a color resist color of the first color resist layer is the same as a color of the anti-peeping sub-pixel corresponding to the first reflective structure.

In some embodiments, the display panel further includes a second reflective structure; the second reflective structure is located in the pixel definition layer and located between two adjacent first reflective structures; and
when the display panel is in an anti-peeping mode, the second reflective structure is configured to reflect external light into the anti-peeping area, and when the display panel is in a normal display mode, the second reflective structure is configured to absorb the external light.

In some embodiments, the second reflective structure includes:
a second reflector, configured to reflect external light;
a second color resist layer, covered on the second reflector; and
a second electrochromic layer, covered on the second color resist layer, the second electrochromic layer is connected to the first anode layer, and the second electrochromic layer has a first state and a second state; when the second electrochromic layer is in the first state, the second electrochromic layer is black in color to absorb the external light, and when the second electrochromic layer is in the second state, the second electrochromic layer is transparent to allow the external light to enter.

In some embodiments, the second color resist layer includes a first color resist unit and a second color resist unit arranged opposite to each other, the first color resist unit and the second color resist unit are arranged on a surface of the second reflector and cover the second reflector; and
a color of the first color resist unit is the same as that of the adjacent anti-peeping sub-pixel, and a color resist color of the second color resist unit is the same as a color of an adjacent anti-peeping sub-pixel.

In some embodiments, a side of the second reflective structure away from the substrate is recessed approaching to a side where the substrate is located, to form a second curved surface.

In some embodiments, a side of at least one of the first reflective structures away from the substrate is recessed approaching to a side where the substrate is located, to form a first curved surface.

In some embodiments, the display panel further includes an encapsulation layer, the encapsulation layer is located on a side of the cathode layer away from the substrate, and the plurality of shading units are located on a side of the encapsulation layer away from the substrate.

In some embodiments, the second anode layer is transparent.

In a second aspect, an embodiment of the present application provides a display device, which includes:
a display panel according to the first aspect; and
a mainboard connected to the display panel.

Traditional OLED displays design a light shielding layer on the anti-peeping sub-pixels, which will lose most of the light of the anti-peeping sub-pixels and reduce the light utilization rate of the anti-peeping sub-pixels. The display panel and the display device provided in the embodiment of the present application improve the light utilization rate of the anti-peeping sub-pixels by innovating the architecture of the display panel. Specifically, by adding the plurality of first reflective structures in the pixel definition layer, the first reflective structures are used to reflect at least part of the lights that are not perpendicular to the thickness direction of the display panel into the anti-peeping area, therefore the light utilization rate of the anti-peeping sub-pixels is improved and the anti-peeping effect is enhanced.

Further, when the external light is strong and the display panel is in the anti-peeping mode, the anti-peeping effect can be enhanced. If the display panel is in the normal display mode, the reflectivity can be reduced to improve the display effect of the panel. This will improve the display quality and display effect of the display panel to a certain extent, and at the same time improve the competitiveness of the panel and customer satisfaction. Specifically, when the anti-peeping sub-pixels are turned on, the light emitted downward passes through the second anode layer and transmits the light to the first reflective structures. The first reflective structures will reflect the light, in this process, the non-orthogonal projected light (light that is not perpendicular to the thickness direction of the display panel) will be reflected to the viewing angle range of the anti-peeping area for anti-peeping.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a structural schematic diagram of a display panel provided in an embodiment of the present application;

FIG. 2 is a structural schematic diagram of a display panel provided in an embodiment of the present application;

FIG. 3 is a schematic diagram of a first reflective structure in a display panel provided in an embodiment of the present application;

FIG. 4 is a schematic diagram of a second reflective structure in a display panel provided in an embodiment of the present application;

FIG. 5 is a first schematic diagram of lights and structure of a display panel provided in an embodiment of the present application;

FIG. 6 is a second schematic diagram of lights and structure of a display panel provided in an embodiment of the present application;

FIG. 7 is a third schematic diagram of lights and structure of a display panel provided in an embodiment of the present application;

FIG. 8 is a schematic diagram of a first reflective structure in a display panel provided in another embodiment of the present application; and

FIG. 9 is a schematic diagram of a second reflective structure in a display panel provided in another embodiment of the present application.

In the Drawings, the reference numerals are listed as following:
10—substrate;
20—drive circuit layer;
30—first anode layer; 31—first anode; 32—third anode; 33—fourth anode;
40—pixel definition layer; 400—first reflective structure; 4000—first curved surface; 401—first reflector; 402—first color resist layer; 403—first electrochromic layer; 410—second reflective structure; 4100—second curved surface; 411—second reflector; 412—second color resist layer; 4121—first color resist unit; 4122—second color resist unit; 413—second electrochromic layer;
50—light-emitting layer; 51—display sub-pixel; 52—anti-peeping sub-pixel;
60—second anode layer; 61—second anode;
70—cathode layer;
80—shading unit; and
90—encapsulation layer.

### DESCRIPTION OF THE EMBODIMENTS

In the following description, specific details such as specific system structure, technology, etc. are presented for illustration rather than qualification in order to fully understand the embodiments of the present application. However, it should be clear to those skilled in the art that the present application may also be realized in other embodiments without these specific details. In other cases, detailed descriptions of well-known systems, devices, circuits and methods are omitted so as not to prejudice the description of the present application with unnecessary details.

It should also be understood that the term “and/or” used in the description of the embodiments of the present application and the attached claims refers to any combination of one or more of the associated listed items and all possible combinations, including these combinations.

It is noted that when a component is referred to as being “fixed to” or “disposed on” another component, it can be directly or indirectly on another component. When a component is referred to as being “connected to” another component, it can be directly or indirectly connected to another component.

In the description of the present application, it needs to be understood that, directions or location relationships indicated by terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn't be considered as any limitation to the present application.

In addition, the terms “first”, “second”, “third”, etc. in the description of the present application and the accompanying claims are used only to distinguish the description and are not to be construed as indicating or implying relative importance.

References to “one embodiment” or “some embodiments”, etc. as described in the description of the present application means that specific features, structures, or features described in conjunction with the embodiments are included in one or more embodiments of the present application. Thus, the terms “in one embodiment”, “in some embodiments”, “in some other embodiments”, “in some further embodiments”, etc., which appear in differences in the specification, do not necessarily all refer to the same embodiments, but mean “one or more but not all embodiments” unless otherwise specifically emphasized. The terms “including”, “containing”, “having” and their variations all mean “including but not limited to” unless otherwise specifically emphasized.

In the prior art, traditional OLED displays design a light shielding layer on the anti-peeping sub-pixels, which will lose most of the light of the anti-peeping sub-pixels and reduce the light utilization rate of the anti-peeping sub-pixels. The display panel and the display device provided in the embodiment of the present application improve the light utilization rate of the anti-peeping sub-pixels by innovating the architecture of the display panel. Specifically, by adding the plurality of first reflective structures in the pixel definition layer, the first reflective structures are used to reflect at least part of the lights that are not perpendicular to the thickness direction of the display panel into the anti-peeping area, therefore the light utilization rate of the anti-peeping sub-pixels is improved and the anti-peeping effect is enhanced. This will improve the display quality and display effect of the display panel to a certain extent, and also improve the competitiveness of the panel and customer satisfaction.

It should be noted that the thickness direction of the display panel mentioned in the embodiments of the present application is the Y direction in the figures, and the X direction is the length/width direction of the display panel. The above is only for the convenience of understanding the technical solution of the embodiments of the present application, and should not be understood as limiting the scope of the embodiments of the present application.

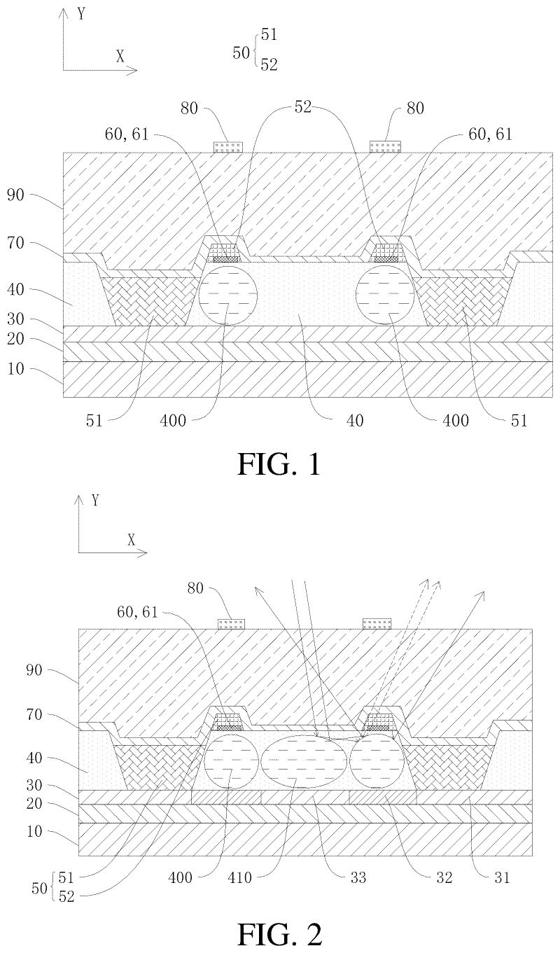

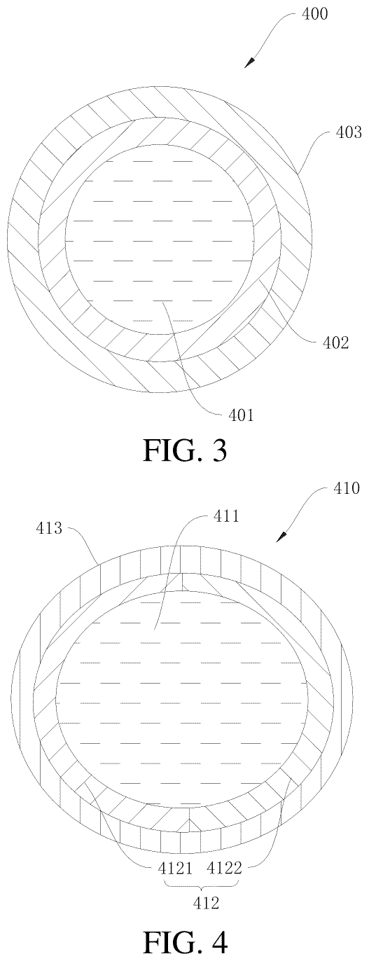

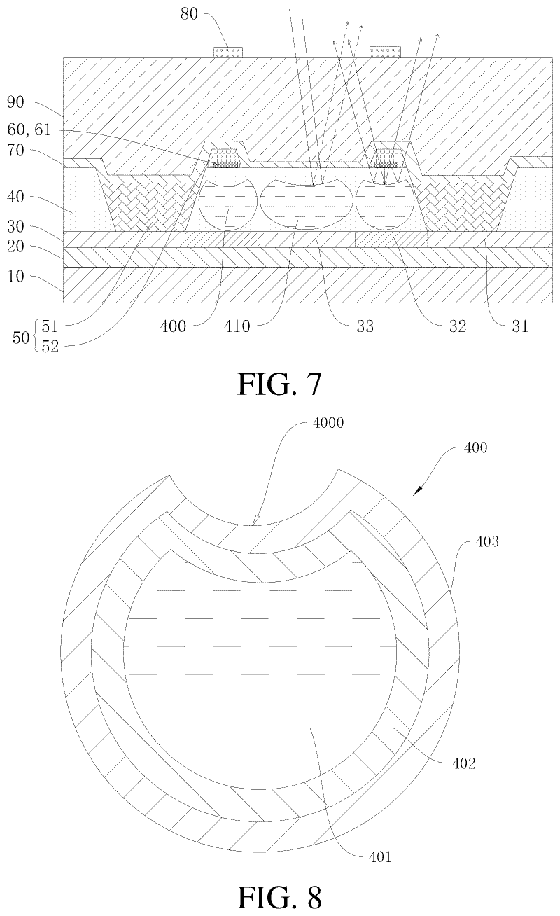

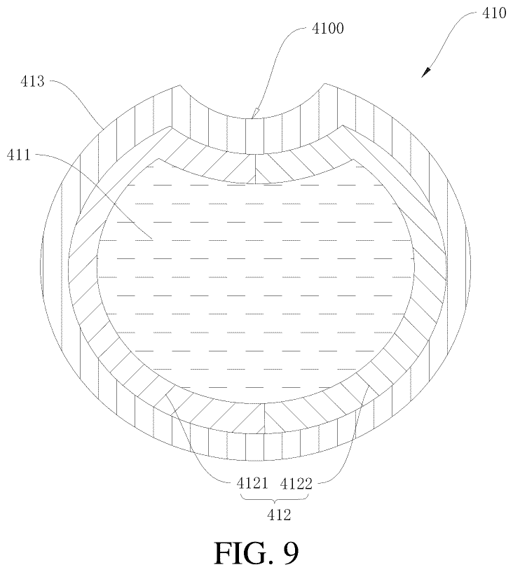

In a first aspect, an embodiment of the present application provides a display panel, as shown in FIG. 1 to FIG. 9, the display panel includes a substrate 10, a drive circuit layer 20, a first anode layer 30, a pixel definition layer 40, a light-emitting layer 50, a second anode layer 60, a cathode layer 70, a plurality of shading units 80, and a plurality of first reflective structures 400.

The drive circuit layer 20 is located on aside of the substrate 10.

The first anode layer 30 is located on a side of the drive circuit layer 20 away from the substrate 10, and the first anode layer 30 includes a plurality of anodes.

The pixel definition layer 40 is arrayed and arranged at intervals on the side of the first anode layer 30 away from the substrate 10, and the pixel definition layer 40 forms an anti-peeping area in the thickness direction of the display panel.

The light-emitting layer 50 includes a plurality of sub-pixels, and the plurality of sub-pixels are connected to the plurality of anodes in a one-to-one correspondence. The plurality of sub-pixels include display sub-pixels 51 and anti-peeping sub-pixels 52. The display sub-pixels 51 are located on the side of the first anode layer 30 away from the substrate 10 and located between two adjacent pixel definition layers 40, and the anti-peeping sub-pixels 52 are located on the side of the pixel definition layer 40 away from the substrate 10, the display sub-pixels 51 form a display area in the thickness direction of the display panel.

The second anode layer 60 is located between the pixel definition layer and the anti-peeping sub-pixels, and the second anode layer 60 includes a plurality of second anodes 61, and the second anodes 61 are connected to the anti-peeping sub-pixels 52 in a one-to-one correspondence.

The cathode layer 70 is located on the side of the light-emitting layer 50 away from the substrate 10;

The plurality of shading units 80 are located on the side of the cathode layer 70 away from the substrate 10, and the shading units 80 correspond to the anti-peeping sub-pixels 52 in a one-to-one correspondence, and the projection of the anti-peeping sub-pixel 52 in the thickness direction of the display panel is located in the shading unit 80 corresponding to the anti-peeping sub-pixel 52.

The plurality of first reflective structures 400 are located in the pixel definition layer 40, and the first reflective structures 400 correspond to the anti-peeping sub-pixels 52 in a one-to-one correspondence, and the projection of the first reflective structures 400 in the thickness direction of the display panel is located in the anti-peeping sub-pixel 52 corresponding to the first reflective structures 400, and the first reflective structures 400 are used to at least reflect part of the lights that are not perpendicular to the thickness direction of the display panel into the anti-peeping area.

The display panel and the display device provided in the embodiment of the present application improve the light utilization rate of the anti-peeping sub-pixels by innovating the architecture of the display panel. Specifically, by adding the plurality of first reflective structures in the pixel definition layer, the first reflective structures are used to reflect at least part of the lights that are not perpendicular to the thickness direction of the display panel into the anti-peeping area, therefore the light utilization rate of the anti-peeping sub-pixels is improved and the anti-peeping effect is enhanced.

In applications, the material of the substrate is usually glass, plastic, flexible metal foil or composite material, etc. The function of the substrate is that: as the basic support structure of the entire display panel, it usually has good flatness and smoothness to ensure the uniformity and stability of subsequent layers. The material of the drive circuit layer is usually made of amorphous silicon or low-temperature polycrystalline silicon to make a thin film transistor; its function is to control the switching state and brightness adjustment of each pixel point, and is responsible for transmitting the electrical signal to the light-emitting layer. The anode layer includes a first anode layer and a second anode layer, and its material is usually a transparent conductive material, such as indium tin oxide or other transparent conductive oxides. The anode layer acts as a positive electrode, and the main function of the anode layer is to inject holes into the light-emitting layer. In some embodiments, the anode layer needs to be transparent to allow light to pass through. The material of the pixel definition layer is usually a photosensitive polymer material, the pixel definition layer is made by a photolithography process; its function is to define the position of each pixel and isolate different pixel areas to prevent the mixing of materials between adjacent pixels. This helps to form a clear pixel boundary. The material of the light-emitting layer is composed of organic light-emitting materials, these materials can be fluorescent materials, phosphorescent materials or other types, depending on the technical route of the display panel; the function of the light-emitting layer is that: when holes and electrons meet in the light-emitting layer, excitons are formed and emit light, so as to produce the color of the image or text. The material of the cathode layer is usually composed of low work function metals such as aluminum and magnesium, or alloys. As a negative electrode, the cathode layer has the main function of extracting electrons from the light-emitting layer. The shielding layer (referred to as a shading unit in the embodiment of the present application) is usually made of black metal or highly light-absorbing organic material; in the anti-peeping display panel, its function is to reduce the visible range when viewed from the side and improve the contrast of the front view. It can reduce unnecessary light leakage and to form a clearer image.

In applications, the light being not perpendicular to the thickness direction of the display panel is the light schematic diagram shown in FIG. 2, that is, the light that are at a certain angle to the thickness direction of the display panel, that is, the light that is incident obliquely, the first reflective structures mainly reflect the obliquely incident light into the anti-peeping area, so as to realize display and viewing from the thickness direction perpendicular to the display panel, and finally achieve the improvement of the anti-peeping effect and the function of the display panel in protecting the privacy of the user.

In some embodiments, as shown in FIG. 1 to FIG. 4, each of the first reflective structures 400 includes a first reflector 401, a first color resist layer 402, and a first electrochromic layer 403.

The first reflector 401 is used to reflect external light and/or light emitted by sub-pixels adjacent to the first reflector.

The first color resist layer 402 is covered on the first reflector 401, and the first color resist layer 402 is used to filter the color of light;

The first electrochromic layer 403 is covered on the first color resist layer 402, and the first electrochromic layer 403 is connected to the first anode layer 30. The first electrochromic layer 403 has a first state and a second state. When the first electrochromic layer is in the first state, the first electrochromic layer 403 is black in color, so as to absorb the external light, thus to improve light utilization and display effect; when the first electrochromic layer is in the second state, the first electrochromic layer 403 is transparent to allow light to enter.

In applications, the working principle of the first reflective structure is as follows:

When the display panel is in the normal display mode, that is, the first electrochromic layer is in the first state and is black in color, which can absorb external light, so as to provide light utilization and improve the display effect.

When the display panel is in the anti-peeping mode, the first electrochromic layer is in the second state, that is, the first electrochromic layer is transparent, and the light emitted by the anti-peeping sub-pixel will sequentially pass through the first electrochromic layer, the first color resist layer, and the first reflector, and the first reflector will reflect the light and reflect the light into the anti-peeping area. In this process, the non-orthogonal projection light (that is, the light that is not perpendicular to the thickness direction of the display panel) will be reflected to the anti-peeping viewing angle range for anti-peeping.

In some embodiments, the color resist color of the first color resist layer is the same as the color of the anti-peeping sub-pixel corresponding to the first reflective structure. In applications, the colors of the anti-peeping sub-pixel usually include three colors: red, green and blue, that is, the color resist color of the first color resist layer and the color of the anti-peeping sub-pixel corresponding to the first reflective structure are the same as red, blue, or green. In this way, light of different colors can be reflected in a targeted manner, so as to improve the anti-peeping effect.

In some embodiments, as shown in FIG. 2 to FIG. 9, the display panel further includes a second reflective structure 410, which is located in the pixel definition layer 40 and located between two adjacent first reflective structures 400;

When the display panel is in the anti-peeping mode, the second reflective structure 410 is used to reflect the external light into the anti-peeping area to enhance the anti-peeping effect of the display panel;

When the display panel is in the normal display mode, the second reflective structure 410 is used to absorb the external light to enhance the display effect of the display panel.

In some embodiments, as shown in FIG. 2 to FIG. 4, the second reflective structure 410 includes a second reflector 411, a second color resist layer 412, and a second electrochromic layer 413.

The second reflector 411 is used to reflect the external light.

The second color resist layer 412 is covered on the second reflector 411, and the second color resist layer 412 is used to filter the color of light.

The second electrochromic layer 413 is covered on the second color resist layer 412, and the second electrochromic layer 413 is connected to the first anode layer 30, and the second electrochromic layer 413 has a first state and a second state. When the second electrochromic layer 413 is in the first state, the second electrochromic layer 413 is black in color, and the entire second reflective structure 410 is used to absorb the external light to enhance the luminous brightness of the display sub-pixel 51, and also improve the overall light utilization rate;

When the second electrochromic layer 413 is in the second state, the second electrochromic layer 413 is transparent, and the external light can pass through the second electrochromic layer 413 and filter by the second color resist layer 412g, and then be reflected by the second reflector 411 into the anti-peeping area to enhance the anti-peeping effect.

In applications, when the external light is strong and the display panel is in the anti-peeping mode, the external light passes through the second electrochromic layer and the second color resist layer of the second reflective structure, and is finally reflected by the second reflector into the anti-peeping viewing angle range to enhance the anti-peeping effect. If the display panel is in the normal display mode, the first anode layer controls the second electrochromic layer in the second reflective structure to be black in color, so as to play the role of absorbing the external light to improve the display effect of the display panel.

In some embodiments, as shown in FIGS. 1 and 2, the first anode layer 30 includes a first anode 31, a third anode 32 and a fourth anode 33, the first anode 31 is connected to the display sub-pixel 51, the third anode 32 is connected to the first electrochromic layer 403 in the first reflective structure 400 to control the state change of the first electrochromic layer 403, and the fourth anode 33 is connected to the second electrochromic layer 413 in the second reflective structure 410 to control the state change of the second electrochromic layer 413.

In some embodiments, as shown in FIG. 2 to FIG. 4, the second color resist layer 412 includes a first color resist unit 4121 and a second color resist unit 4122 arranged opposite to each other, and the first color resist unit 4121 and the second color resist unit 4122 are arranged on the surface of the second reflector 411 and cover the second reflector 411.

The first color resist unit 4121 has the same color as the adjacent anti-peeping sub-pixel 52, and the color resist color of the second color resist unit 4122 is the same as the color of the adjacent anti-peeping sub-pixel 52.

In applications, the colors of anti-peeping sub-pixels usually include three colors: red, green, and blue, that is, the color resist color of the first color resist unit is the same as the color of the anti-peeping sub-pixel closest to the first color resist unit, which is red, blue, or green. Similarly, the color resist color of the second color resist unit is the same as the color of the anti-peeping sub-pixel closest to the second color resist unit, which is red, blue, or green. In this way, light of different colors can be reflected in a targeted manner, so as to improve the anti-peeping effect.

In applications, the first reflector and the second reflector are three-dimensional structures, usually regular three-dimensional structures such as spheres, ellipsoids, and cylinders. In other embodiments, they can also be irregular three-dimensional structures. In some embodiments, the first color resist layer is a coating applied on the first reflector, and the first electrochromic layer is a coating applied on the first color resist layer. Similarly, the second reflector, the second color resist layer, and the second electrochromic layer are of the same or similar design. The difference is that the second color resist layer has at least two colors, that is, the first color resist unit can be red, the second color resist unit can be green, the first color resist unit can be green, the second color resist unit can be red, and the first color resist unit can be red. Moreover, the specific shapes of the first reflective structure and the second reflective structure can be the same or different.

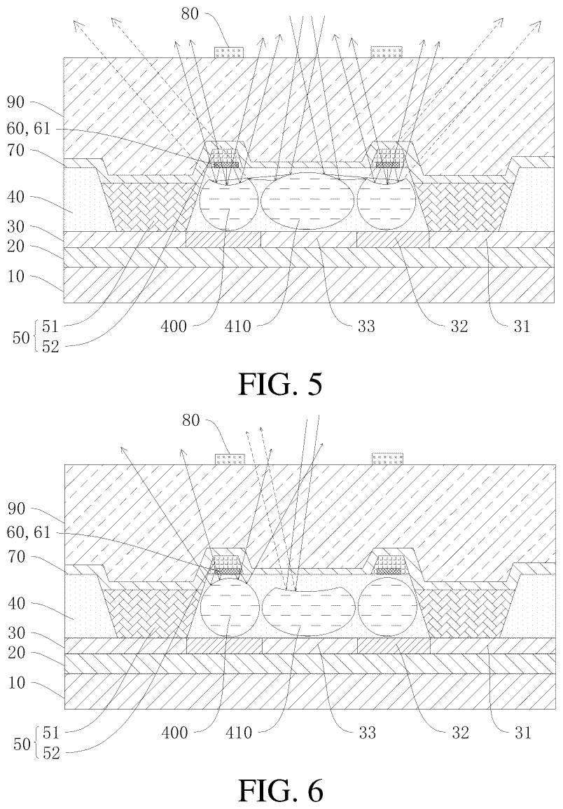

In some embodiments, as shown in FIGS. 5 to 9, a side of at least one first reflective structure 400 away from the substrate 10 is concavely arranged close to the side where the substrate 10 is located, to form a first curved surface 4000. This arrangement is to increase the area of external light incident on the first reflective structure 400. By arranging the side of the first reflective structure 400 away from the substrate 10 concave inward to form a first curved surface 4000 to increase the incident area, more external light can be incident on the surface of the first reflective structure 400 at more angles, and then the light is reflected into the anti-peeping area to further enhance the anti-peeping effect. In applications, all first reflective structures 400 are concave inward to form the first curved surfaces 4000. In this way, the anti-peeping effect of each part of the display panel can be uniform and the same to achieve wide-angle anti-peeping.

In some embodiments, as shown in FIGS. 5 to 9, the side of the second reflective structure 410 away from the substrate 10 is concavely arranged close to the side where the substrate 10 is located to form a second curved surface 4100. In other words, the side of the second reflective structure 410 away from the substrate 10 is concave inward to form a second curved surface 4100. Similar to the function of the first curved surface 4000, it also effectively increases the incident area and incident angle of the external light, so that more external light is incident on the second reflective structure 410 at more angles. According to the specific application state of the display panel, when in the anti-peeping mode, the second reflective structure 410 can reflect external light to the anti-peeping area according to the interaction of the second reflector 411, the second color resist layer 412 and the second electrochromic layer 413, so as to improve the light utilization rate of the anti-peeping sub-pixel 52, and to achieve the anti-peeping effect of the display panel; when the display panel is in the normal display mode, the second electrochromic layer 413 of the second reflective structure 410 is black in color, so that the second reflective structure 410 can absorb the external light to improve the luminous brightness of the display sub-pixel 51 to improve the display effect.

In some embodiments, as shown in FIGS. 1 to 9, the display panel further includes an encapsulation layer 90, the encapsulation layer 90 is located on the side of the cathode layer 70 away from the substrate 10, and the shading unit 80 is located on the side of the encapsulation layer 90 away from the substrate 10. In applications, the encapsulation layer 90 is an important component of the organic light-emitting diode display panel, and its main purpose is to protect the light-emitting layer 50 from water vapor and oxygen, since these factors will cause the OLED material to degrade and shorten the life of the display panel. The encapsulation layer 90 is usually located at the outermost layer of the display panel and covered on the cathode layer 70.

The material of the encapsulation layer usually uses inorganic materials such as glass or ceramics to provide a high-strength physical barrier to effectively isolate water vapor and oxygen. Its main function is to isolate water vapor and oxygen to prevent water vapor and oxygen from penetrating into the OLED layer, to extend the service life of the display panel, and also provide physical protection for the display panel to prevent damage to the OLED layer by the external environment, as well as anti-scratch, so as to improve the wear resistance and scratch resistance of the display panel and to improve display quality and enhance reliability.

The second aspect of the embodiment of the present application provides a display device, the display device includes the display panel described in the first aspect of the embodiment of the present application and the mainboard (not shown in the figure), and the mainboard is connected to the display panel.

The display device provided by the embodiment of the present application can effectively improve the anti-peeping effect and display effect, thereby effectively improving the display quality of the display device, and ultimately improving the favorability of customers.

In the above embodiments, the description of each embodiment has its own emphasis. For the part that is not described or recorded in detail in a certain embodiment, please refer to the relevant description of other embodiments.

The above embodiments are only used to illustrate the technical solutions of the embodiments of the present application, but not to limit them; although the embodiments of the present application are described in detail with reference to the above embodiments, those skilled in the art should understand that they can still modify the technical solutions recorded in the above embodiments, or replace some of the technical features therein by equivalent; and these modifications or replacements do not make the essence of the corresponding technical solutions deviate from the spirit and scope of the technical solutions of the embodiments of the present application, and should be included in the protection scope of the embodiments of the present application.

What is claimed is:

1. A display panel, comprising:
a substrate;
a drive circuit layer, located on a side of the substrate;
a first anode layer, located on a side of the drive circuit layer away from the substrate, wherein the first anode layer comprises a plurality of anodes;
a pixel definition layer, arrayed and arranged at intervals on a side of the first anode layer away from the substrate, wherein the pixel definition layer forms an anti-peeping area in a thickness direction of the display panel;
a light-emitting layer, comprising a plurality of sub-pixels, wherein the plurality of sub-pixels are connected to the plurality of anodes in a one-to-one correspondence, the plurality of sub-pixels comprise display sub-pixels and anti-peeping sub-pixels, the display sub-pixels are located on a side of the first anode layer away from the substrate and located between two adjacent pixel definition layers, the anti-peeping sub-pixels are located on a side of the pixel definition layer away from the substrate, and the display sub-pixels form a display area in the thickness direction of the display panel;
a second anode layer, located between the pixel definition layer and the anti-peeping sub-pixels, wherein the second anode layer comprises a plurality of second anodes, and the plurality of second anodes are connected to the plurality of anti-peeping sub-pixels in a one-to-one correspondence;
a cathode layer, located on a side of the light-emitting layer away from the substrate;
a plurality of shading units, located on a side of the cathode layer away from the substrate, wherein the plurality of shading units are connected to the plurality of anti-peeping sub-pixels in a one-to-one correspondence, and a projection of each anti-peeping sub-pixel in the thickness direction of the display panel is located in the shading unit corresponding to the anti-peeping sub-pixel; and
a plurality of first reflective structures, located in the pixel definition layer, wherein the plurality of first reflective structures are connected to the plurality of anti-peeping sub-pixels in a one-to-one correspondence, and a projection of each first reflective structure in the thickness direction of the display panel is located in the anti-peeping sub-pixel corresponding to the first reflective structure, and the first reflective structure is configured to reflect at least part of lights that are not perpendicular to the thickness direction of the display panel into the anti-peeping area.

2. The display panel according to in claim 1, wherein each of the plurality of first reflective structures comprises:
a first reflector, configured to reflect external light and/or light emitted by the sub-pixel adjacent to the first reflector;
a first color resist layer, covered on the first reflector, wherein the first color resist layer is configured to filter a color of light; and
a first electrochromic layer, covered on the first color resist layer, wherein the first electrochromic layer is connected to the first anode layer, the first electrochromic layer has a first state and a second state, the first electrochromic layer is black in color when the first electrochromic layer is in the first state, and the first electrochromic layer is transparent when the first electrochromic layer is in the second state for light to enter.

3. The display panel according to claim 2, wherein a color resist color of the first color resist layer is the same as a color of the anti-peeping sub-pixel corresponding to the first reflective structure.

4. The display panel according to claim 1, further comprises a second reflective structure; the second reflective structure is located in the pixel definition layer and located between two adjacent first reflective structures;
wherein when the display panel is in an anti-peeping mode, the second reflective structure is configured to reflect external light into the anti-peeping area, and when the display panel is in a normal display mode, the second reflective structure is configured to absorb the external light.

5. The display panel according to claim 4, wherein the second reflective structure comprises:
a second reflector, configured to reflect external light;
a second color resist layer, covered on the second reflector; and
a second electrochromic layer, covered on the second color resist layer, wherein the second electrochromic layer is connected to the first anode layer, and the second electrochromic layer has a first state and a second state; when the second electrochromic layer is in the first state, the second electrochromic layer is black in color to absorb the external light, and when the second electrochromic layer is in the second state, the second electrochromic layer is transparent to allow the external light to enter.

6. The display panel according to claim 5, wherein the second color resist layer comprises a first color resist unit and a second color resist unit arranged opposite to each other, wherein the first color resist unit and the second color resist unit are arranged on a surface of the second reflector and cover the second reflector; and
wherein a color of the first color resist unit is the same as that of the adjacent anti-peeping sub-pixel, and a color resist color of the second color resist unit is the same as a color of an adjacent anti-peeping sub-pixel.

7. The display panel according to claim 4, wherein a side of the second reflective structure away from the substrate is recessed approaching to a side where the substrate is located, to form a second curved surface.

8. The display panel according to claim 1, wherein a side of at least one of the first reflective structures away from the substrate is recessed approaching to a side where the substrate is located, to form a first curved surface.

9. The display panel according to claim 2, wherein a side of at least one of the first reflective structures away from the substrate is recessed approaching to a side where the substrate is located, to form a first curved surface.

10. The display panel according to claim 1, wherein the display panel further comprises an encapsulation layer, the encapsulation layer is located on a side of the cathode layer away from the substrate, and the plurality of shading units are located on a side of the encapsulation layer away from the substrate.

11. The display panel according to claim 2, wherein the display panel further comprises an encapsulation layer, the encapsulation layer is located on a side of the cathode layer away from the substrate, and the plurality of shading units are located on a side of the encapsulation layer away from the substrate.

12. A display device, comprising:
a display panel; and
a mainboard connected to the display panel;
wherein display panel comprises:
a substrate;
a drive circuit layer, located on a side of the substrate;
a first anode layer, located on a side of the drive circuit layer away from the substrate, wherein the first anode layer comprises a plurality of anodes;
a pixel definition layer, arrayed and arranged at intervals on a side of the first anode layer away from the substrate, wherein the pixel definition layer forms an anti-peeping area in a thickness direction of the display panel;
a light-emitting layer, comprising a plurality of sub-pixels, wherein the plurality of sub-pixels are connected to the plurality of anodes in a one-to-one correspondence, the plurality of sub-pixels comprise display sub-pixels and anti-peeping sub-pixels, the display sub-pixels are located on a side of the first anode layer away from the substrate and located between two adjacent pixel definition layers, the anti-peeping sub-pixels are located on a side of the pixel definition layer away from the substrate, and the display sub-pixels form a display area in the thickness direction of the display panel;
a second anode layer, located between the pixel definition layer and the anti-peeping sub-pixels, wherein the second anode layer comprises a plurality of second anodes, and the plurality of second anodes are connected to the plurality of anti-peeping sub-pixels in a one-to-one correspondence;
a cathode layer, located on a side of the light-emitting layer away from the substrate;
a plurality of shading units, located on a side of the cathode layer away from the substrate, wherein the plurality of shading units are connected to the plurality of anti-peeping sub-pixels in a one-to-one correspondence, and a projection of each anti-peeping sub-pixel in the thickness direction of the display panel is located in the shading unit corresponding to the anti-peeping sub-pixel; and
a plurality of first reflective structures, located in the pixel definition layer, wherein the plurality of first reflective structures are connected to the plurality of anti-peeping sub-pixels in a one-to-one correspondence, and a projection of each first reflective structure in the thickness direction of the display panel is located in the anti-peeping sub-pixel corresponding to the first reflective structure, and the first reflective structure is configured to reflect at least part of lights that are not perpendicular to the thickness direction of the display panel into the anti-peeping area.

13. The display device according to claim 12, wherein each of the plurality of first reflective structures comprises:
a first reflector, configured to reflect external light and/or light emitted by the sub-pixel adjacent to the first reflector;
a first color resist layer, covered on the first reflector, wherein the first color resist layer is configured to filter a color of light; and
a first electrochromic layer, covered on the first color resist layer, wherein the first electrochromic layer is connected to the first anode layer, the first electrochromic layer has a first state and a second state, the first electrochromic layer is black in color when the first electrochromic layer is in the first state, and the first electrochromic layer is transparent when the first electrochromic layer is in the second state for light to enter.

14. The display device according to claim 13, wherein a color resist color of the first color resist layer is the same as a color of the anti-peeping sub-pixel corresponding to the first reflective structure.

15. The display device according to claim 12, further comprises a second reflective structure; the second reflective structure is located in the pixel definition layer and located between two adjacent first reflective structures;
wherein when the display panel is in an anti-peeping mode, the second reflective structure is configured to reflect external light into the anti-peeping area, and when the display panel is in a normal display mode, the second reflective structure is configured to absorb the external light.

16. The display device according to claim 15, wherein the second reflective structure comprises:
a second reflector, configured to reflect external light;
a second color resist layer, covered on the second reflector; and
a second electrochromic layer, covered on the second color resist layer, wherein the second electrochromic layer is connected to the first anode layer, and the second electrochromic layer has a first state and a second state; when the second electrochromic layer is in the first state, the second electrochromic layer is black in color to absorb the external light, and when the second electrochromic layer is in the second state, the second electrochromic layer is transparent to allow the external light to enter.

17. The display device according to claim 16, wherein the second color resist layer comprises a first color resist unit and a second color resist unit arranged opposite to each other, wherein the first color resist unit and the second color resist unit are arranged on a surface of the second reflector and cover the second reflector; and
wherein a color of the first color resist unit is the same as that of the adjacent anti-peeping sub-pixel, and a color resist color of the second color resist unit is the same as a color of an adjacent anti-peeping sub-pixel.

18. The display device according to claim 15, wherein a side of the second reflective structure away from the substrate is recessed approaching to a side where the substrate is located, to form a second curved surface.

19. The display device according to claim 12, wherein a side of at least one of the first reflective structures away from the substrate is recessed approaching to a side where the substrate is located, to form a first curved surface.

20. The display device according to claim 12, wherein the display panel further comprises an encapsulation layer, the encapsulation layer is located on a side of the cathode layer away from the substrate, and the plurality of shading units are located on a side of the encapsulation layer away from the substrate.
